(19) United States
(12) Patent Application Publication
(10) Pub. No.: US 2018/0073146 A1
(43) Pub. Date: Mar. 15, 2018

(54) Antenna Device, Plasma Generating Device Using the Same, and Plasma Processing Apparatus

(71) Applicant: TOKYO ELECTRON LIMITED, Tokyo (JP)

(72) Inventors: Hitoshi KATO, Iwate (JP); Takeshi KOBAYASHI, Iwate (JP)

(21) Appl. No.: 15/695,236

(22) Filed: Sep. 5, 2017

(30) Foreign Application Priority Data
Sep. 9, 2016 (JP) 2016-176551

(51) Int. Cl. C23C 16/505; C23C 16/458; H01J 37/32; H01Q 3/01

(52) U.S. Cl. CPC C23C 16/505; C23C 16/458; H01J 2237/3321; H01Q 3/01; H01J 37/3211

(57) ABSTRACT

There is provided an antenna device which includes: a plurality of antenna members installed to extend along a predetermined circling shape having a longitudinal direction and a lateral direction, the antenna members including end portions connected to each other so as to form a pair in which connection portions in the longitudinal direction face each other in the lateral direction; deformable conductive connection members configured to connect the end portions of the plurality of antenna members adjacent to each other; and at least two vertical movement mechanisms individually installed in at least two of the plurality of antenna members and configured to change a bending angle of the antenna members using the connection members as fulcrums by vertically moving the at least two of the plurality of antenna members.

### CROSS-REFERENCE TO RELATED APPLICATION

This application is based upon and claims the benefit of priority from Japanese Patent Application No. 2016-176551, filed on Sep. 9, 2016, the entire contents of which are incorporated herein by reference.

### TECHNICAL FIELD

The present disclosure relates to an antenna device, a plasma generating device using the same, and a plasma processing apparatus.

### BACKGROUND

A plasma-generating gas can be converted into plasma by inductive coupling using a film forming apparatus which includes an antenna installed to face a substrate mounting region of a rotary table so as to extend from a central portion to an outer peripheral portion of the rotary table installed inside a vacuum container. The antenna is disposed so that a separation distance between the antenna and the central portion of the rotary table in the substrate mounting region is larger than a separation distance between the antenna and the outer peripheral portion of the rotary table by 3 mm or more. Further, the antenna includes a plurality of linear portions and node portions for connecting the linear portions to each other. The antenna is configured to be bendable at the node portions.

Such a film forming apparatus includes a pull-up mechanism for pulling up the antenna positioned at the side of the central portion of the rotary table and a mechanism for tilting the antenna with the pull-up mechanism.

However, in the aforementioned configuration, the bending of the antenna is not automated although the pull-up operation of the antenna is automated. Since the proper plasma intensity distribution varies from process to process, it is preferable to change the bent shape of the antenna for each process. In such a case, if it is not possible to automatically change the bent shape of the antenna, it is necessary for a worker to detach the antenna from the apparatus to make adjustments. Thus, the yield decreases because of the labor intensive adjustments.

### SUMMARY

Some embodiments of the present disclosure provide an antenna device, a plasma generating device using the same, and a plasma processing apparatus, which are capable of automatically changing the shape of an antenna.

According to one embodiment of the present disclosure, there is provided an antenna device which includes: a plurality of antenna members installed to extend along a predetermined circling shape having a longitudinal direction and a lateral direction, the antenna members including end portions connected to each other so as to form a pair in which connection portions in the longitudinal direction face each other in the lateral direction; deformable conductive connection members configured to connect the end portions of the plurality of antenna members adjacent to each other; and at least two vertical movement mechanisms individually installed in at least two of the plurality of antenna members and configured to change a bending angle of the antenna members using the connection members as fulcrums by vertically moving the at least two of the plurality of antenna members.

According to another embodiment of the present disclosure, there is provided a plasma generating device which includes: the aforementioned antenna device; and a high-frequency power source configured to supply a high-frequency power to the antenna device.

According to another embodiment of the present disclosure, there is provided a plasma processing apparatus which includes: a process chamber; a susceptor installed inside the process chamber and configured to mount a substrate on a surface thereof; and the aforementioned plasma generating device installed on an upper surface of the process chamber.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic vertical sectional view of an example of a plasma processing apparatus according to an embodiment of the present disclosure.

FIG. 2 is a schematic plan view of an example of a plasma processing apparatus according to an embodiment of the present disclosure.

FIG. 3 is a sectional view taken along a concentric circle of a susceptor of a plasma processing apparatus according to an embodiment of the present disclosure.

FIG. 4 is a vertical sectional view of an example of a plasma generating part of a plasma processing apparatus according to an embodiment of the present disclosure.

FIG. 5 is an exploded perspective view of an example of a plasma generating part of a plasma processing apparatus according to an embodiment of the present disclosure.

FIG. 6 is a perspective view of an example of a housing installed in a plasma generating part of a plasma processing apparatus according to an embodiment of the present disclosure.

FIG. 7 is a vertical sectional view of a vacuum container taken along a rotational direction of a susceptor of a plasma processing apparatus according to an embodiment of the present disclosure.

FIG. 8 is an enlarged perspective view showing a plasma-processing gas nozzle installed in a plasma process region of a plasma processing apparatus according to an embodiment of the present disclosure.

FIG. 9 is a plan view of an example of a plasma generating part of a plasma processing apparatus according to an embodiment of the present disclosure.

FIG. 10 is a perspective view showing a portion of a Faraday shield installed in a plasma generating part of a plasma processing apparatus according to an embodiment of the present disclosure.

FIG. 11 is a perspective view of an antenna device and a plasma generating device according to an embodiment of the present disclosure.

FIG. 12 is a side view of an antenna device and a plasma generating device according to an embodiment of the present disclosure.

FIG. 13 is a side view of an example of an antenna of an antenna device and a plasma generating device according to an embodiment of the present disclosure.

FIGS. 14A to 14D are views showing examples of various shapes of an antenna of an antenna device and a plasma generating device according to an embodiment of the present disclosure.

FIGS. 15A to 15D are views showing implementation results of an antenna device, a plasma generating device and a plasma processing apparatus according to an embodiment of the present disclosure.

### DETAILED DESCRIPTION

Hereinafter, modes for carrying out the present disclosure will be described with reference to the drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Configuration of Plasma Processing Apparatus]

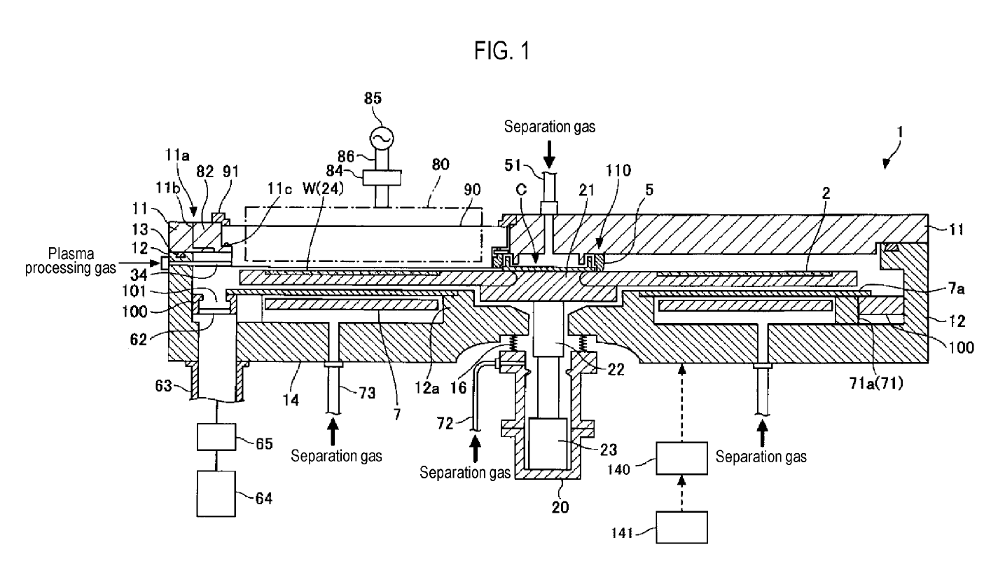

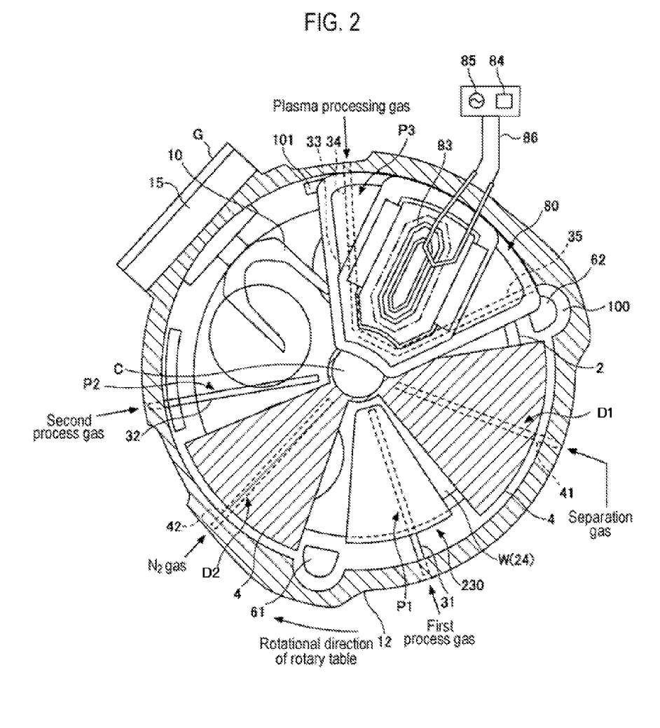

FIG. 1 shows a schematic vertical sectional view of an example of a plasma processing apparatus according to an embodiment of the present disclosure. In addition, FIG. 2 shows a schematic plan view of an example of a plasma processing apparatus according to the present embodiment. In FIG. 2, a top plate 11 is omitted for the sake of convenience in illustration and description.

As shown in FIG. 1, the plasma processing apparatus according to the present embodiment includes a vacuum container 1 having a substantially circular planar shape, and a susceptor 2 installed inside the vacuum container 1 and configured to cause wafers W to revolve about a rotational center coinciding with the center of the vacuum container 1.

The vacuum container 1 is a process chamber in which the wafers W are accommodated and a plasma process is performed on a film or the like formed on a surface of each of the wafers W. The vacuum container 1 includes the top plate (ceiling portion) 11 installed at a position facing recesses 24 (to be described later) of the susceptor 2, and a container body 12. In addition, a seal member 13 having a ring shape is installed in a peripheral edge portion of an upper surface of the container body 12. The top plate 11 is configured to be detachable from the container body 12. The diameter dimension (inner diameter dimension) of the vacuum container 1 in a plan view may be, but is not limited to, for example, about 1,100 mm.

A separation gas supply pipe 51 configured to supply a separation gas for preventing different process gases from being mixed in a central region C inside the vacuum container 1 is connected to the center portion of the upper surface in the vacuum container 1.

The susceptor 2 is fixed to a core portion 21 having a substantially cylindrical shape at the central portion thereof. A driving part 23 rotates the susceptor 2 about a vertical axis, for example, clockwise in FIG. 2, with respect to a rotational shaft 22 connected to a lower surface of the core portion 21 and extending in the vertical direction. The diameter dimension of the susceptor 2 may be, but is not limited to, for example, about 1,000 mm.

The rotational shaft 22 and the driving part 23 are accommodated in a case body 20. In the case body 20, a flange portion at the upper surface side of the case body 20 is airtightly attached to a lower surface of a bottom surface portion 14 of the vacuum container 1. A purge gas supply pipe 72 for supplying a nitrogen gas or the like as a purge gas (separation gas) below the susceptor 2 is connected to the case body 20.

An outer peripheral portion close to the core portion 21 in the bottom surface portion 14 of the vacuum container 1 is formed in a ring shape so as to be adjacent to the susceptor 2 from below, thereby forming a protrusion portion 12a.

In the surface portion of the susceptor 2, circular recesses 24 for mounting wafers W having a diameter of, for example, 300 mm thereon are formed as substrate mounting regions. The recesses 24 are formed at a plurality of locations, for example, five locations, along the rotational direction of the susceptor 2. Each of the recesses 24 has an inner diameter slightly larger (specifically about 1 to 4 mm) than the diameter of the wafers W. The depth of the recess 24 is substantially equal to the thickness of the wafer W or larger than the thickness of the wafer W. Therefore, when the wafer W is accommodated in the recess 24, the surface of the wafer W is flush with or lower than the surface of the region of the susceptor 2 where the wafer W is not mounted. Even when the depth of the recess 24 is set larger than the thickness of the wafer W, it is preferred that the depth of the recess 24 is up to about three times of the thickness of the wafer W. This is because, if the depth of the recess 24 is too large, the film formation may be affected. In the bottom surface of each of the recesses 24, there are formed through-holes (not shown) through which, for example, three lift pins (to be described later) penetrate to push each of the wafers W from below and to raise and lower each of the wafers W.

As shown in FIG. 2, a first process region P1, a second process region P2 and a third process region P3 are formed apart from each other along the rotational direction of the susceptor 2. The third process region P3 is a plasma process region and thus, may be hereinafter referred to as a plasma process region P3. At positions facing the passage regions of the recesses 24 in the susceptor 2, a plurality of, for example, seven gas nozzles 31, 32, 33, 34, 35, 41 and 42 made of, for example, quartz are radially arranged in a spaced-apart relationship in the circumferential direction of the vacuum container 1. These gas nozzles 31 to 35, 41 and 42 are arranged between the susceptor 2 and the top plate 11. These gas nozzles 31 to 35, 41 and 42 are attached so as to extend horizontally, for example, in a facing relationship with the wafers W from the outer peripheral wall of the vacuum container 1 toward the central region C thereof. On the other hand, the gas nozzle 35 extends from the outer peripheral wall of the vacuum container 1 toward the central region C, and subsequently, is bent so as to linearly extend counterclockwise (in the direction opposite to the rotational direction of the susceptor 2) along the central region C. In the embodiment shown in FIG. 2, the plasma-processing gas nozzles 33 and 34, the plasma-processing gas nozzle 35, the separation gas nozzle 41, the first process gas nozzle 31, the separation gas nozzle 42 and the second process gas nozzle 32 are arranged in the named order clockwise from the below-described transfer port 15 (in the rotational direction of the susceptor 2). A gas supplied from the second process gas nozzle 32 often has the same nature as gases supplied from the plasma-processing gas nozzles 33 to 35. When the gases are sufficiently supplied from the plasma-processing gas nozzles 33 to 35, it is not necessarily required to install the second process gas nozzle 32.

In addition, the plasma-processing gas nozzles 33 to 35 may be replaced by a single plasma-processing gas nozzle. In this case, for example, similar to the second process gas nozzle 32, the single plasma-processing gas nozzle extending from the outer peripheral wall of the vacuum container 1 toward the central region C may be installed.

The first process gas nozzle 31 constitutes a first process gas supply part. Furthermore, the second process gas nozzle 32 constitutes a second process gas supply part. Moreover, each of the plasma-processing gas nozzles 33 to 35 constitutes a plasma-processing gas supply part. In addition, each of the separation gas nozzles 41 and 42 constitutes a separation gas supply part.

Each of the nozzles 31 to 35, 41 and 42 is connected to a gas supply source (not shown) via a flow rate control valve.

In the lower surface side (the side facing the susceptor 2) of these nozzles 31 to 35, 41 and 42, gas discharge holes 36 for discharging the aforementioned gases therethrough are formed at a plurality of locations along the radial direction of the susceptor 2, for example, at regular intervals. Each of the nozzles 31 to 35, 41 and 42 is disposed such that a separation distance between the lower edge of each of the nozzles 31 to 35, 41 and 42 and the upper surface of the susceptor 2 is, for example, about 1 to 5 mm.

A region below the first process gas nozzle 31 is a first process region P1 for causing a first process gas to be adsorbed on the wafer W. A region below the second process gas nozzle 32 is a second process region P2 in which a second process gas capable of reacting with the first process gas to generate a reaction product, is supplied to the wafer W. In addition, a region below each of the plasma-processing gas nozzles 33 to 35 is a third process region P3 in which a modification process is performed with respect to a film formed on the wafer W. The separation gas nozzles 41 and 42 are installed to form first and second separation regions D1 and D2 by which the first process region P1 and the third process region P3 and the second process region P2 and the first process region P1 are respectively separated. No separation region D is formed between the second process region P2 and the third process region P3. In the second process gas supplied to the second process region P2 and the mixed gas supplied to the third process region P3, the mixed gas may often contain some of the same components contained in the second process gas. Thus, there is no need to intentionally separate the second process region P2 and the third process region P3 using a separation gas.

As will be described in detail later, a source gas constituting a main component of a film to be formed is supplied as a first process gas from the first process gas nozzle 31. For example, when the film to be formed is a silicon oxide film (SiO₂ film), a silicon-containing gas such as an organic aminosilane gas or the like is supplied. A reaction gas capable of reacting with the source gas to generate a reaction product is supplied as a second process gas from the second process gas nozzle 32. For example, when the film to be formed is a silicon oxide film (SiO₂ film), an oxidizing gas such as an oxygen gas, an ozone gas or the like is supplied. In order to modify the film thus formed, a mixed gas containing the same gas as the second process gas and a noble gas is supplied from the plasma-processing gas nozzles 33 to 35. In this regard, the plasma-processing gas nozzles 33 to 35 are structured to supply a gas to different regions on the susceptor 2. Thus, ratios of flow rates of the noble gases are made different for each region so that the modification process is uniformly performed as a whole.

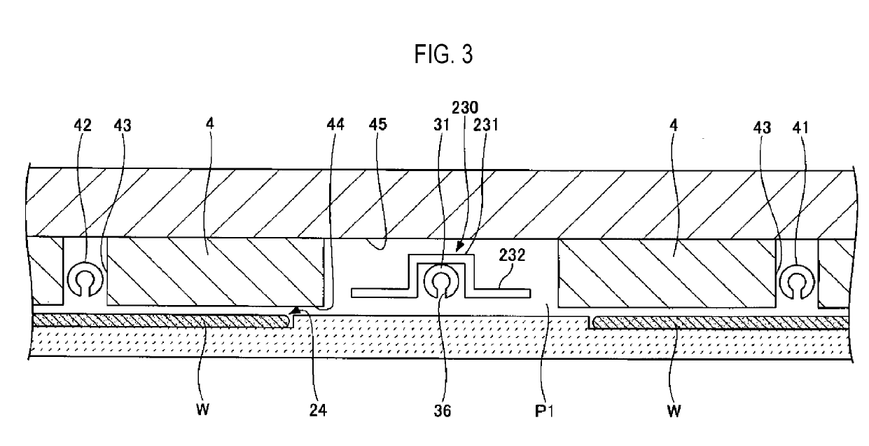

FIG. 3 is a sectional view of the susceptor of the plasma processing apparatus according to the present embodiment, which is taken along a concentric circle. Furthermore, FIG. 3 is a sectional view taken from the first separation region D1 to the second separation region D2 via the first process region P1.

Substantially fan-shaped convex portions 4 are formed in the top plate 11 of the vacuum container 1 in the first and second separation region D1 and D2. The convex portions 4 are attached to the back surface of the top plate 11. Inside the vacuum container 1, there are formed a lower flat ceiling surface 44 (a first ceiling surface) as a lower surface of the convex portion 4, and an upper ceiling surface 45 (a second ceiling surface) higher than the ceiling surface 44 and located at both sides of the first ceiling surface 44 in the circumferential direction.

As shown in FIG. 2, the convex portion 4 forming the ceiling surface 44 has a fan-like planar shape in which the top portion is cut in an arc shape. In the convex portion 4, a groove portion 43 extending in the radial direction is formed at the circumferential center. Each of the separation gas nozzles 41, 42 is accommodated in the groove portion 43. In order to inhibit the mixing of the respective process gases, the peripheral edge portion of the convex portion 4 (the portion at the outer edge side of the vacuum container 1) is bent in an L shape so that it is opposed to the outer end face of the susceptor 2 and slightly spaced apart from the container body 12.

A nozzle cover 230 is installed above the first process gas nozzle 31 so as to allow the first process gas to flow along the wafers W and allow the separation gas to flow along the top plate 11 of the vacuum container 1 while bypassing the vicinity of the wafers W. As shown in FIG. 3, the nozzle cover 230 includes a substantially box-shaped cover body 231 whose lower surface side is opened so as to accommodate the first process gas nozzle 31, and baffle plates 232 which are plate-like bodies respectively connected to upstream and downstream sides in the rotational direction of the susceptor 2 at the opened lower surface side of the cover body 231. A side wall surface of the cover body 231 at the rotational central side of the susceptor 2 extends toward the susceptor 2 so as to face the tip portion of the first process gas nozzle 31. A side wall surface of the cover body 231 at the outer edge side of the susceptor 2 is cut out so as not to interfere with the first process gas nozzle 31.

As shown in FIG. 2, a plasma generating device 80 is installed above the plasma-processing gas nozzles 33 to 35 in order to convert the plasma-processing gas discharged into the vacuum container 1 to plasma.

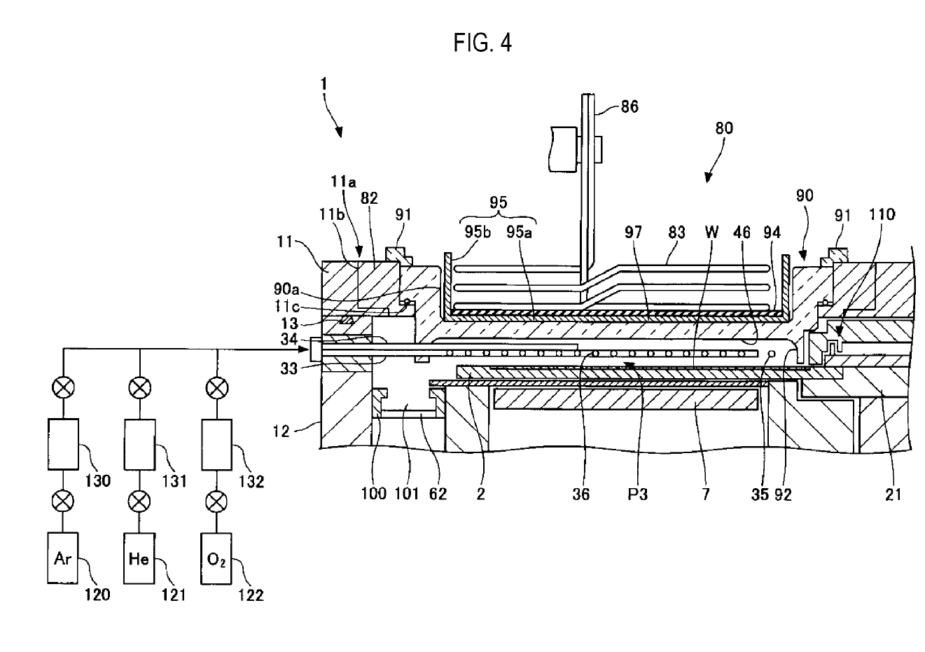

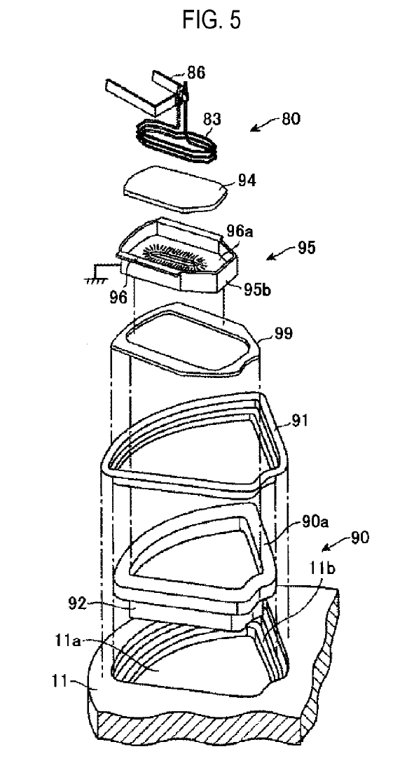

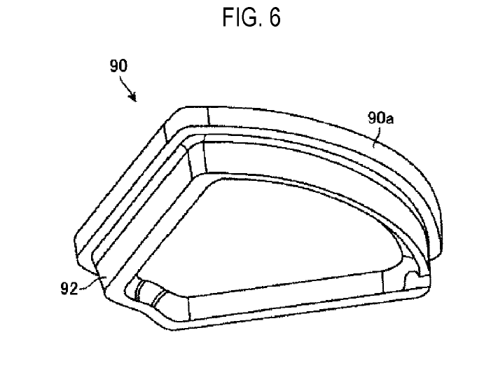

FIG. 4 shows a vertical sectional view of an example of a plasma generating part according to the present embodiment. Further, FIG. 5 shows an exploded perspective view of an example of a plasma generating part according to the present embodiment. Moreover, FIG. 6 shows a perspective view of an example of a housing installed in the plasma generating part according to the present embodiment.

The plasma generating device 80 is made by winding an antenna 83, which is formed of a metal wire or the like, in a coil shape, for example, three times around a vertical axis. The plasma generating device 80 is disposed so as to surround a band-like body region extending in the radial direction of the susceptor 2 in a plan view and so as to extend across the diameter portion of the wafer W mounted on the susceptor 2.

The antenna 83 is connected to a high-frequency power source 85 having a frequency of, for example, 13.56 MHz and an output power of, for example, 5000 W via a matcher 84. The antenna 83 is installed so as to be airtightly partitioned from the inner region of the vacuum container 1. As illustrated in FIGS. 1 and 3, there is installed a connection electrode 86 for electrically connecting the antenna 83 to the matcher 84 and the high-frequency power source 85.

The antenna 83 is configured to be bent up and down. A vertical movement mechanism capable of automatically bending the antenna 83 up and down is also provided. However, details thereof are omitted in FIG. 2. The details will be described later.

As shown in FIGS. 4 and 5, an opening portion 11a, which is opened in a fan shape in a plan view, is formed in the top plate 11 disposed above the plasma-processing gas nozzles 33 to 35.

As shown in FIG. 4, an annular member 82 is airtightly installed in the opening portion 11a along the opening edge portion of the opening portion 11a. A casing 90 described later is airtightly installed at the inner peripheral surface side of the annular member 82. That is to say, the annular member 82 is airtightly installed at a position where the outer peripheral side thereof faces an inner peripheral surface 11b facing the opening portion 11a of the top plate 11 and the inner peripheral side thereof faces a flange portion 90a of the casing 90 described later. The casing 90 made of a derivative such as quartz or the like is installed in the opening portion 11a via the annular member 82 in order to position the antenna 83 below the top plate 11. The bottom surface of the casing 90 constitutes the ceiling surface 46 of the plasma process region P3.

As shown in FIG. 6, the casing 90 is formed so that the upper peripheral edge portion thereof extends horizontally in a flange shape along the circumferential direction to form a flange portion 90a and the central portion thereof is recessed toward the inner region of the vacuum container 1 positioned below the casing 90 in a plan view.

When the wafer W is positioned below the casing 90, the casing 90 is disposed so as to straddle the diameter portion of the wafer W in the radial direction of the susceptor 2. A seal member 11 c such as an O-ring or the like is installed between the annular member 82 and the top plate 11.

An internal atmosphere of the vacuum container 1 is airtightly set via the annular member 82 and the casing 90. Specifically, the annular member 82 and the casing 90 are dropped into the opening portion 11a. Then, on the upper surfaces of the annular member 82 and the casing 90, the casing 90 are pressed downward over the circumferential direction by a pressing member 91 formed in a frame shape so as to extend along a contact portion between the annular member 82 and the casing 90. Further, the pressing member 91 is fixed to the top plate 11 by bolts or the like (not shown). As a result, the internal atmosphere of the vacuum container 1 is set to be airtight. In FIG. 5, the annular member 82 is omitted for the sake of simplicity.

As shown in FIG. 6, a projection 92 vertically extending toward the susceptor 2 is formed on the lower surface of the casing 90 so as to surround the plasma process region P3 on the lower side of the casing 90 along the circumferential direction. The above-described plasma-processing gas nozzles 33 to 35 are accommodated in a region surrounded by the inner peripheral surface of the projection 92, the lower surface of the casing 90 and the upper surface of the susceptor 2. The projection 92 at proximal end portions of the plasma-processing gas nozzles 33 to 35 (at the inner wall side of the vacuum container 1) is cut out in a substantially arc shape so as to conform to the contour of the plasma-processing gas nozzles 33 to 35.

As shown in FIG. 4, the projection 92 is formed in the circumferential direction at the lower side of the casing 90 (at the side of the plasma process region P3). The seal member 11 c is isolated from the plasma process region P3 by the projection 92 without being directly exposed to plasma. Therefore, even if plasma tries to diffuse from the plasma process region P3, for example, toward the seal member 11c, the plasma is deactivated before reaching the seal member 11c because the plasma goes through the lower side of the projection 92.

Further, as shown in FIG. 4, the plasma-processing gas nozzles 33 to 35 are installed in the plasma process region (the third process region) P3 below the casing 90 and are connected to an argon gas supply source 120, a helium gas supply source 121 and an oxygen gas supply source 122. Flow rate controllers 130, 131 and 132 are respectively installed between the plasma-processing gas nozzles 33 to 35 and the argon gas supply source 120, the helium gas supply source 121 and the oxygen gas supply source 122. An Ar gas, a He gas and an O₂ gas are supplied from the argon gas supply source 120, the helium gas supply source 121 and the oxygen gas supply source 122 to the plasma-processing gas nozzles 33 to 35 via the respective flow rate controllers 130, 131 and 132 at a predetermined flow rate ratio (mixing ratio). The Ar gas, the He gas and the O₂ gas are determined depending on the region to be supplied.

In the case where a single plasma-processing gas nozzle is used, for example, a mixed gas of the Ar gas, the He gas and the O₂ gas is supplied to the single plasma-processing gas nozzle.

FIG. 7 is a vertical sectional view of the vacuum container 1 taken along the rotational direction of the susceptor 2. As shown in FIG. 7, the susceptor 2 rotates clockwise during the plasma process. Thus, an N₂ gas tries to enter below the casing 90 through a gap between the susceptor 2 and the projection 92 as the susceptor 2 rotates. Therefore, in order to prevent the entry of the N₂ gas below the casing 90 through the gap, a gas is discharged from below the casing 90 toward the gap. Specifically, as shown in FIGS. 4 and 7, the gas discharge holes 36 of the plasma generating gas nozzle 33 are arranged so as to face the gap, namely the upstream side in the rotational direction of the susceptor 2 and to orient downward. The angle θ of the gas discharge holes 36 of the plasma generating gas nozzle 33 with respect to the vertical axis may be, for example, about 45 degrees as shown in FIG. 7, or may be about 90 degrees so that the gas discharge holes 36 face the inner surface of the projection 92. In other words, depending on the application, the angle θ of the gas discharge holes 36 may be set within a range of about 45 to 90 degrees which can appropriately prevent the entry of the N₂ gas.

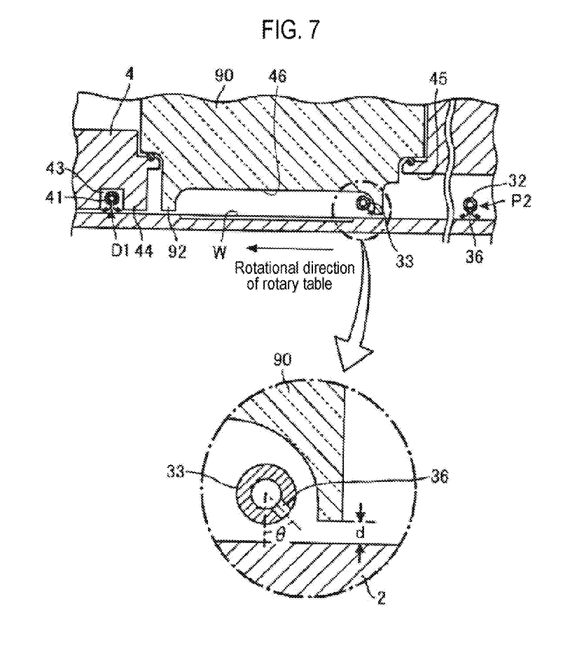

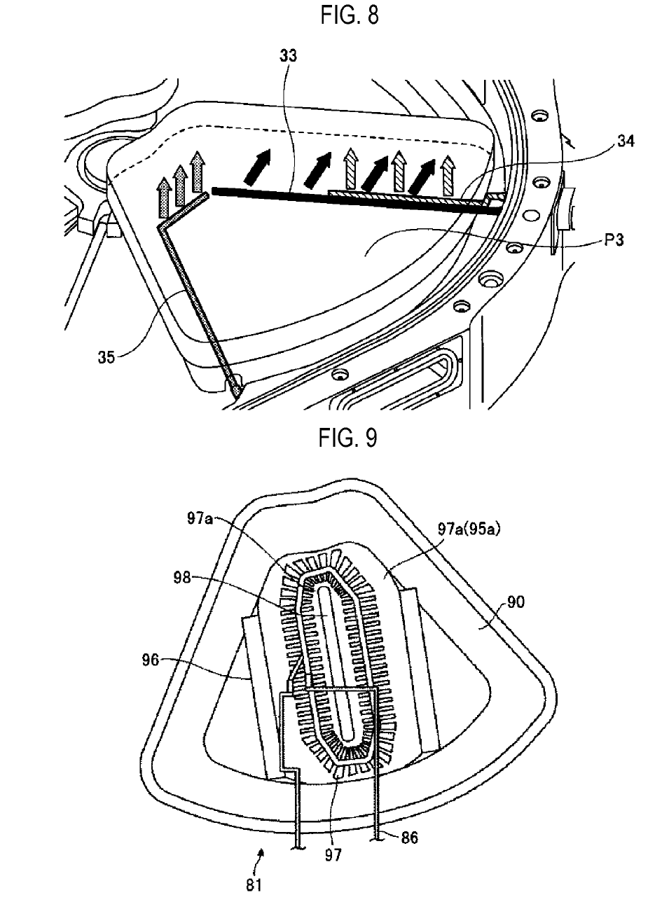

FIG. 8 is an enlarged perspective view showing the plasma-processing gas nozzles 33 to 35 installed in the plasma process region P3. As shown in FIG. 8, the plasma-processing gas nozzle 33 is a nozzle capable of covering the entire recess 24 on which the wafer W is mounted, and capable of supplying a plasma-processing gas to the entire surface of the wafer W. On the other hand, the plasma-processing gas nozzle 34 is a nozzle having a length of about one half of the length of the plasma-processing gas nozzle 33 and installed slightly above the plasma-processing gas nozzle 33 so as to substantially overlap with the plasma-processing gas nozzle 33. The plasma-processing gas nozzle 35 extends from the outer peripheral wall of the vacuum container 1 along the radius of the fan-shaped plasma process region P3 at the downstream side in the rotational direction of the susceptor 2. The plasma-processing gas nozzle 35 has a linearly-curved shape so as to extend along the central region C in the vicinity of the central region C. Hereinafter, for the ease of distinction, the plasma-processing gas nozzle 33 covering the entire recess 24 is referred to as a base nozzle 33, the plasma-processing gas nozzle 34 covering only the outer side is referred to as an outer nozzle 34, and the plasma-processing gas nozzle 35 extending to the inside is referred to as an axis side nozzle 35.

The base nozzle 33 is a gas nozzle for supplying the plasma-processing gas to the entire surface of the wafer W. As described with reference to FIG. 7, the base nozzle 33 discharges the plasma-processing gas toward the projection 92 that constitutes the lateral surface defining the plasma process region P3.

On the other hand, the outer nozzle 34 is a nozzle for supplying the plasma-processing gas mainly to the outer region of the wafer W.

The axis side nozzle 35 is a nozzle for supplying the plasma-processing gas mainly to the central region of the wafer W close to the axis side of the susceptor 2.

In the case where a single plasma-processing gas nozzle is used, only the base nozzle 33 may be installed.

Next, the Faraday shield 95 of the plasma generating device 80 will be described in more detail. As shown in FIGS. 4 and 5, a metal plate which is a conductive plate-like body formed to substantially conform to an internal shape of the casing 90, for example, a grounded Faraday shield 95 made of copper or the like, is accommodated in the upper side of the casing 90. The Faraday shield 95 includes a horizontal surface 95a formed horizontally along the bottom surface of the casing 90, and a vertical surface 95b extending upward from the outer end of the horizontal surface 95a in the circumferential direction. The Faraday shield 95 may be configured to have, for example, a substantially hexagonal shape in a plan view.

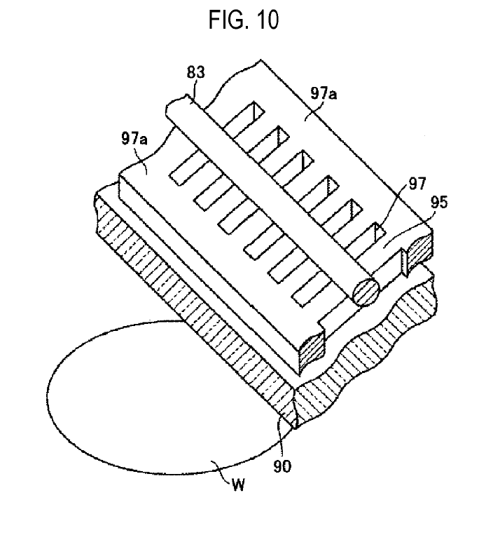

FIG. 9 is a plan view showing an example of the plasma generating device 80 in which the details of the structure of the antenna 83 and the vertical movement mechanism are omitted. FIG. 10 is a perspective view showing a portion of the Faraday shield 95 installed in the plasma generating device 80.

Upper end edges of the Faraday shield 95 at right and left sides when viewing the Faraday shield 95 from the rotational center of the susceptor 2 extend horizontally toward the right and left sides to form support portions 96. Between the Faraday shield 95 and the casing 90, there is installed a frame-shaped body 99 which supports the support portions 96 from below and which is supported by the flange portions 90a at the side of the central region C of the casing 90 and at the outer edge portion side of the susceptor 2.

When an electric field reaches the wafer W, electrical wirings and the like formed inside the wafer W may be electrically damaged in some cases. Therefore, as shown in FIG. 10, a large number of slits 97 are formed in the horizontal surface 95a so as to prevent the electric field component of an electric field and a magnetic field (electromagnetic field) generated in the antenna 83 from going to the wafer W positioned below the horizontal surface 95a and so as to allow the magnetic field to reach the wafer W.

As shown in FIGS. 9 and 10, the slits 97 are formed below the antenna 83 in the circumferential direction so as to extend in a direction orthogonal to the winding direction of the antenna 83. In this regard, the slits 97 are formed to have a width dimension of about 1/10,000 or less of a wavelength corresponding to the high frequency supplied to the antenna 83. Conductive paths 97a formed of grounded conductors or the like are disposed in the circumferential direction at one longitudinal end side and the other longitudinal end side of the respective slits 97 so as to close opening ends of the slits 97. In the Faraday shield 95, an opening portion 98 for checking the light emission state of plasma is formed in a region set apart from the region where the slits 97 are formed, namely at the center of the region where the antenna 83 is wound. In FIG. 2, the slits 97 are omitted for the sake of simplicity. An example of the formation region of the slits 97 is indicated by a one-dot chain line.

As shown in FIG. 5, on the horizontal surface 95a of the Faraday shield 95, an insulating plate 94 made of quartz or the like and having a thickness dimension of, for example, about 2 mm is laminated in order to ensure insulation between the Faraday shield 95 and the plasma generating device 80 mounted above the Faraday shield 95. That is to say, the plasma generating device 80 is disposed so as to cover the inside of the vacuum container 1 (the wafers W mounted on the susceptor 2) via the casing 90, the Faraday shield 95 and the insulating plate 94.

Next, the antenna device 81 and the plasma generating device 80 according to the embodiment of the present disclosure will be described in more detail.

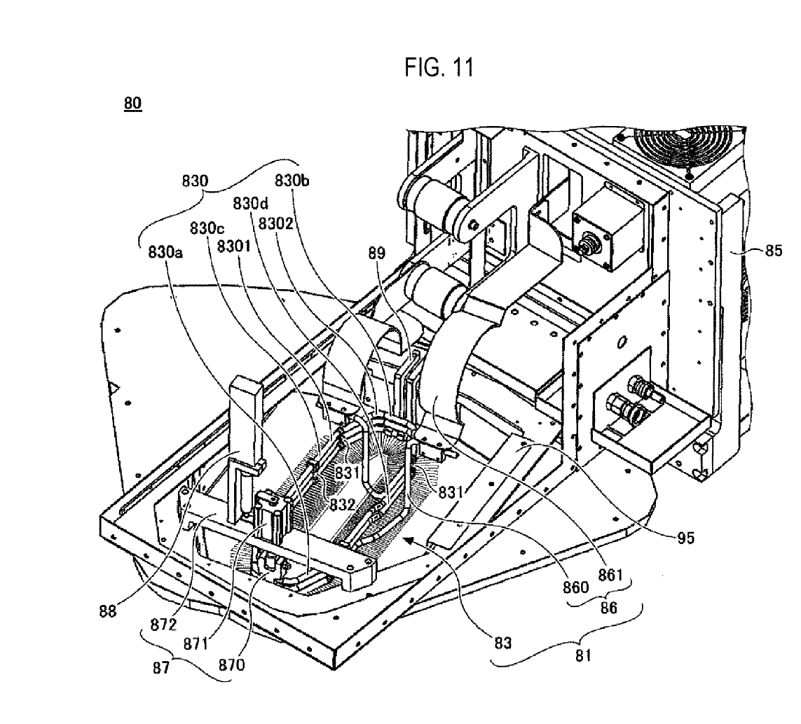

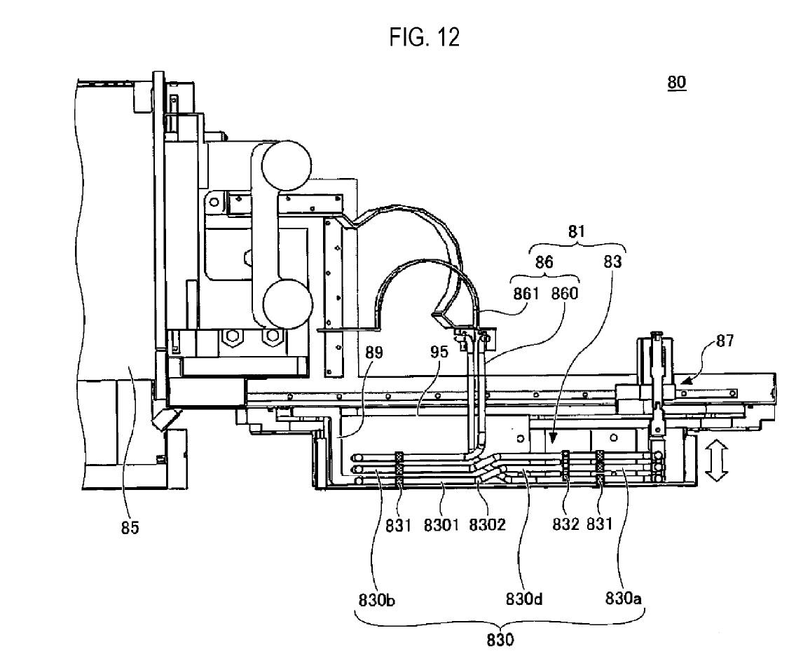

FIG. 11 is a perspective view of the antenna device 81 and the plasma generating device 80 according to the embodiment of the present disclosure. FIG. 12 is a side view of the antenna device 81 and the plasma generating device 80 according to the embodiment of the present disclosure.

The antenna device 81 includes the antenna 83, a connection electrode 86, a vertical movement mechanism 87, a linear encoder 88 and a fulcrum jig 89.

In addition, the plasma generating device 80 further includes the antenna device 81, the matcher 84 and the high frequency power source 85.

The antenna 83 includes antenna members 830, connection members 831 and spacers 832. The antenna 83 is configured in a coil shape and a circling shape as a whole and is configured in an elongated annular shape having a longitudinal direction and a lateral direction (or a width direction) in a plan view. As a planar shape, the antenna 83 has a shape close to an ellipse having corners or a rectangular frame having corners. Such a circular shape of the antenna 83 is formed by connecting the antenna members 830. The antenna members 830 are members constituting a portion of the antenna 83. The antenna 83 is formed by connecting the end portions of a plurality of small antenna members 830 extending along the circular shape. Each of the antenna members 830 includes linear portions 8301 having a linear shape and curved portions 8302 having a curved shape for bending and connecting the linear portions 8301.

By combining and connecting the linear portions 8301 and the curved portions 8302, the antenna members 830 are formed such that both end portions 830a and 830b and the central portions 830c and 830d are connected to each other to form a circular shape as a whole. In FIG. 11, the antenna 83 has an overall shape in which both end portions 830a and 830b have a shape close to a circular arc and the central portions 830c and 830d have a linear shape. The antenna members 830a and 830b of both end portions having a shape close to a circular arc are connected to each other by the antenna members 830c and 830d of the central portion having a linear shape. The antenna members 830c and 830d of the central portion are opposed to each other in a substantially parallel fashion. In general, the antenna 83 has such a shape that the antenna members 830c and 830d form a long side and the antenna members 830a and 830b form a short side.

Further, as shown in FIG. 11, the antenna members 830a and 830b are formed in a shape close to a circular arc by connecting three linear portions 8301 to each other with two curved portions 8302. The antenna member 830c is formed of one long linear portion 8301. Moreover, as shown in FIGS. 11 and 12, the antenna member 830d is configured such that two long linear portions 8301 and one short linear portion between the two long linear portions 8301 are installed to have a step difference in the vertical direction and are connected by two small curved portions 8302.

The antenna members 830 form a circular shape so as to be multi-stages as a whole. In FIGS. 11 and 12, there are shown the antenna members 830 that form a three-stage circling shape.

The connection members 831 are members for connecting the adjacent antenna members 830 to each other and are made of a material which is conductive and deformable. The connection members 831 may be formed of, for example, a flexible substrate or the like and may be made of copper as the material thereof. Since copper is a soft material having high electrical conductivity, it is suitable for connecting the antenna members 830 to each other.

Since the connection members 831 are made of a flexible material, it is possible to bend the antenna members 830 using the connection members 831 as fulcrums. As a result, the antenna members 830 can be maintained in a bent state at the positions of the connection members 831. Thus, the three-dimensional shape of the antenna 83 can be variously changed. The distance between the antenna 83 and the wafer W affects the plasma process intensity. When the antenna 83 is brought close to the wafer W, the plasma process intensity becomes high. When the antenna 83 is moved away from the wafer W, the plasma process intensity tends to become low.

When the wafers W are mounted on the recesses 24 of the susceptor 2 and the susceptor 2 is rotated to perform the plasma process, the movement velocity at the center side of the susceptor 2 is low and the movement velocity at the outer peripheral side of the susceptor 2 is high. This is because the wafers W are arranged along the circumferential direction of the susceptor 2. Thus, the plasma process intensity (or the process amount) at the center side of the wafer W which is irradiated with plasma for a long time tends to be higher than the plasma process intensity at the outer peripheral side. In order to correct this, for example, if the antenna member 830a of the end portion disposed at the center side is bent upward and the antenna member 830b disposed at the outer peripheral side is bent downward, it is possible to lower the plasma process intensity at the center side and to increase the plasma process intensity at the outer peripheral side. This makes it possible to equalize the entire plasma process amount in the radial direction of the susceptor 2.

In FIG. 11, four connection members 831 are installed in order to connect the four antenna members 830a to 830d. However, the number of the antenna members 830 and the connection members 831 may be increased or decreased depending on the application. At minimum, the antenna members 830a and 830b may exist in both end portions. The antenna members 830a and 830b may be formed in an elongated U shape so as to extend from both end portions to the central portion. Two antenna members 830a and 830b may be connected by two connection members 831. In addition, when it is desired to variously change the shape of the antenna 83, four antenna members 830 may be disposed in the central portion so as to increase bendable portions.

In any case, it is preferable that the positions of the opposing connection members 831 are the same in the longitudinal direction, namely that the lengths of the opposing antenna members 830 in the longitudinal direction are equal to each other. As described above, the antenna 83 may be configured such that the height in the longitudinal direction is adjustable and the bent portions are opposed to each other in the lateral direction and aligned in the longitudinal direction. In the present embodiment, the connection member 831 connecting the antenna member 830a and the antenna member 830c, and the connection member 831 connecting the antenna member 830a and the antenna member 830d are opposed to each other in the lateral direction and located at the same position in the longitudinal direction. Likewise, the connection member 831 connecting the antenna member 830b and the antenna member 830c, and the connection member 831 connecting the antenna member 830b and the antenna member 830d are also opposed to each other in the lateral direction and located at the same position in the longitudinal direction. With such a configuration, it is possible to change the shape of the antenna 83 so as to adjust the plasma process intensity in the longitudinal direction.

However, when it is desired to perform deformation just like a parallelogram by obliquely shifting the bent portions, it may be possible to adopt a configuration in which the bent portions are not directly opposed to each other in the lateral direction but opposed to each other in the oblique direction, and the positions of the connection members 831 in the longitudinal direction are set at different positions at the antenna member 830c side and the antenna member 830d side.

The spacers 832 are members for vertically separating the multistage antenna members 830 so that the antenna members 830 at the upper and lower stages do not make contact with each other and a short circuit does not occur even if the antenna 83 is deformed.

The vertical movement mechanism 87 is a vertical movement mechanism for vertically moving the antenna members 830. The vertical movement mechanism 87 includes an antenna holding part 870, a driving part 871 and a frame 872. The antenna holding part 870 is to hold the antenna 83. The driving part 871 is to vertically move the antenna 83 via the antenna holding part 870. The antenna holding part 870 may have various configurations as long as it can hold the antenna members 830 of the antenna 83. For example, as shown in FIG. 12, the antenna holding part 870 may be configured to cover the antenna members 830 and hold the antenna members 830.

Various driving means may be used as the driving part 871 as long as they can move the antenna members 830 up and down. For example, an air cylinder which performs air driving may be used. In FIG. 12, an example is illustrated in which an air cylinder is applied to the drive part 871 of the vertical movement mechanism 87. In addition, a motor or the like may be used as the vertical movement mechanism 87.

The frame 872 is a supporting part for holding the driving part 871 and is configured to hold the driving part 871 at an appropriate position. The antenna holding part 870 is held by the driving part 871.

The vertical movement mechanisms 87 are individually installed in at least two or more of the antenna members 830a to 830d. In the present embodiment, the deformation of the antenna 83 is automatically adjusted by the vertical movement mechanism 87 and not by an operator. Therefore, in order to deform the antenna 83 into various shapes, it is preferable that the vertical movement mechanisms 87 are individually installed in the respective antenna members 830a to 830d and are independently operated. Thus, the vertical movement mechanisms 87 may be individually installed in the respective antenna members 830a to 830d. In the case where the vertical movement mechanisms 87 are not installed in all the antenna members 830a to 830d, the vertical movement mechanisms 87 may be installed in at least two of the antennas members 830a to 830d.

Although only one vertical movement mechanism 87 is shown in FIGS. 11 and 12, a plurality of vertical movement mechanisms 87 may be individually installed in the antenna members 830a to 830d to be bent. For example, if the vertical movement mechanism 87 for vertically moving the antenna member 830a is installed at the center side in the rotational direction of the susceptor 2 and if the vertical movement mechanisms 87 for vertically moving the antenna members 830c and 830d are additionally installed, it is possible to deform the antenna member 830a, 830c and 830d into an arbitrary shape. At that time, for example, when it is desired to bend the antenna member 830a of the center side end portion upward, the antenna member 830a is pulled up by the respective vertical movement mechanism 87, and the antenna members 830c and 830d are fixed or pulled down by the respective vertical movement mechanisms 87, whereby the antenna 83 may be deformed through the cooperation of a plurality of vertical movement mechanisms 87. In the case where the connection members 831 are sufficiently flexible and the antenna 83 can be bent only by the vertical movement of the respective vertical movement mechanisms 87, such an operation is not necessarily performed. However, when there is a need to apply a certain level of force to deform the antenna 83 even if the connection members 831 are flexible, the bending operation of the antenna 83 may be performed through the cooperation of a plurality of vertical movement mechanisms 87 as described above.

The bending of the antenna 83 is performed by using the connecting members 831 as fulcrums and changing the angle formed by the antenna members 830a to 830d, which sandwich the connection members 831, and the connection members 831.

The linear encoder 88 is a device that detects the position of a linear shaft and outputs the detected position as position information. The linear encoder 88 can accurately measure the distance from the upper surface of the Faraday shield 95 to the antenna member 830a. The linear encoder 88 may be installed at an arbitrary position where accurate position information is obtained. A plurality of linear encoders 88 may be installed. Further, the linear encoder 88 may be any one of an optical type, a magnetic type and an electromagnetic induction type as long as it can detect the position and height of the antenna 83. In addition, a height measuring means other than the linear encoder 88 may be used as long as it can measure the position and the height of the antenna 83.

The fulcrum jig 89 is a member for rotatably fixing the antenna member 830 existing at the lowermost stage. The fulcrum jig 89 can easily tilt the antenna 83. The fulcrum jig 89 is generally installed so as to support the antenna member 830b existing at the lowermost stage of the end portion at the outer peripheral side. This is because the antenna 83 is often deformed so as to raise the center side as described above. However, it is not essential to install the fulcrum jig 89. Rather, it is preferable to install the vertical movement mechanism 87 to vertically move the antenna member 830b.

The connection electrode 86 includes an antenna connection portion 860 and an adjustment bus bar 861. The connection electrode 86 is a connection wiring that supplies the high frequency power outputted from the high-frequency power source 85 to the antenna 83. The antenna connection portion 860 is a connection wiring directly connected to the antenna 83. The adjustment bus bar 861 is a portion which has elasticity so as to absorb the deformation of the antenna connection portion 860 when the antenna connection portion 860 moves up and down with the vertical movement of the antenna 83. Since the adjustment bus bar 861 is an electrode, the adjustment bus bar 861 is wholly made of a conductive material such as metal or the like.

As described above, according to the antenna device 81 and the plasma generating device 80 according to the embodiment of the present disclosure, the shape of the antenna 83 can be automatically deformed into an arbitrary shape. Thus, it is possible to deform the shape of the antenna 83 into an appropriate shape depending on the process. This makes it possible to flexibly and easily perform the plasma process with high in-plane uniformity.

When deforming the antenna 83 depending on the process, for example, the shape of the antenna 83 to be selected may be specified for each recipe. The determination thereof may be made by a control part 140. The control part 140 may be configured to instruct the vertical movement mechanism 87 to deform the antenna 83 into an appropriate shape.

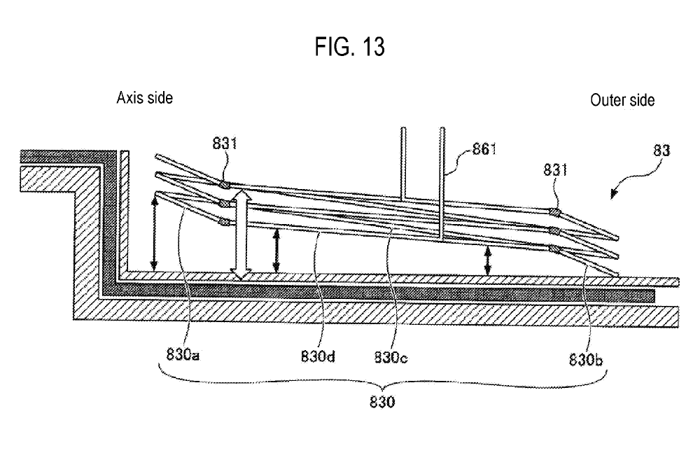

FIG. 13 is a side view of the antenna 83 of the antenna device 81 and the plasma generating device 80 according to the embodiment of the present disclosure. As shown in FIG. 13, the bending angle of the antenna members 830 may be changed variously using the connection members 831 as fulcrums. The height of the antenna members 830 may also be changed depending on the location.

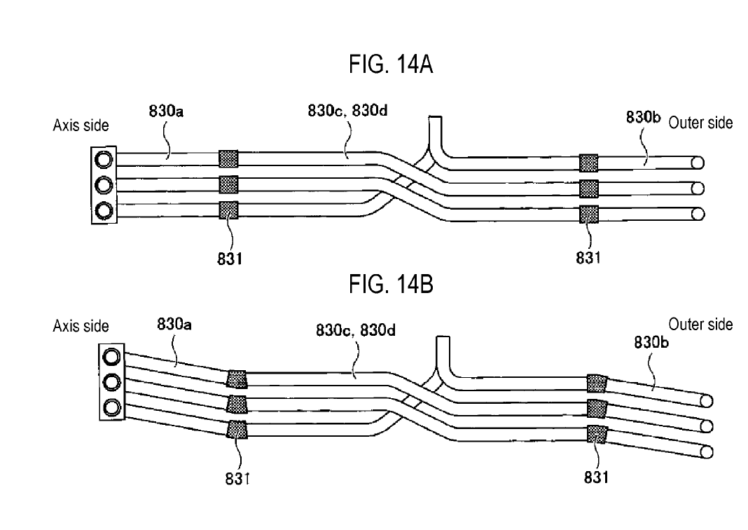

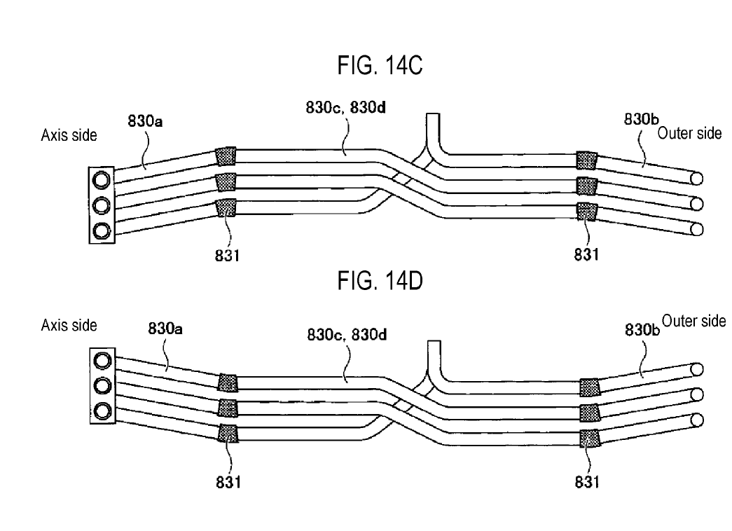

FIGS. 14A to 14D are views showing examples of various shapes of the antenna 83. As shown in FIGS. 14A to 14D, in the antenna device 81 and the plasma generating device 80 according to the embodiment of the present disclosure, the shape of the antenna 83 can be variously changed depending on the process. In FIGS. 14A to 14D, the left side is the central axis side of the susceptor 2, and the right side is the outer peripheral side of the susceptor 2.

FIG. 14A is a view showing an example of a lateral surface shape of the antenna 83 deformed into a straight type. In the straight type, only the antenna member 830a at the central axis side is pulled up without changing the shape of the antenna 83. As a result, the plasma process at the axis side can be weakened and the plasma process at the outer peripheral side can be made to be relatively intensive.

FIG. 14B is a view showing an example of a lateral surface shape of the antenna 83 deformed into a transformer type. In the transformer type, the antenna member 830a at the central axis side is bent so as to be pulled upward, the antenna member 830b at the outer peripheral side is bent so as to be pulled downward, and the antenna members 830c and 830d in the center portion are kept substantially horizontal. As a result, even in the case of the straight type shown in FIG. 14A, the amount of plasma process at the central axis side can be greatly reduced and the amount of plasma process at the outer peripheral side can be greatly increased. Thus, it is possible to correct the imbalance of plasma process, which is caused by the difference in the distance from the center. This makes it possible to perform uniform plasma processing.

FIG. 14C is a view showing an example of a lateral surface shape of the antenna 83 deformed into a sheath type. In the sheath type, the antenna member 830a at the central axis side and the antenna member 830b at the outer peripheral side are pulled down to strengthen the plasma process at both end portions in the radial direction. For example, as for the property of plasma, plasma containing hydrogen tends to spread spatially, and plasma not containing hydrogen tends to shrink spatially. Examples of the plasma containing hydrogen may include H₂, NH₃ and the like. Examples of the plasma not containing hydrogen may include O₂, Ar and the like.

That is to say, in the case of forming a nitride film, plasma tends to spatially spread. In the case of forming an oxide film, plasma tends to spatially shrink. The sheath type has a shape suitable for suppressing the spatial spreading of plasma and is therefore suitable for forming a nitride film. As described above, the shape of the antenna 83 for performing the uniform plasma process varies depending on the kind of the film to be formed, namely the process. Thus, the automatic deformation of the antenna 83 using the vertical movement mechanism 87 or the like has great significance in improving the process efficiency.

FIG. 14D is a view showing an example of a lateral surface shape of the antenna 83 deformed into an inverted sheath type. As described above, in the case of forming an oxide film, O₂ is used. Thus, plasma tends to shrink. The inverted sheath type antenna 83 configured to spread plasma has a shape suitable for forming an oxide film. Therefore, in the case of forming an oxide film, the inverted sheath type may be adopted.

In this way, the suitable antenna varies depending on the process. Therefore, by automatically deforming the antenna 83 into an appropriate shape for each process, it is possible to perform the plasma process with high throughput and high in-plane uniformity.

Other constituent elements of the plasma processing apparatus according to the present embodiment will be described again.

At the outer peripheral side of the susceptor 2, a side ring 100 as a cover body is disposed slightly lower than the susceptor 2 as shown in FIG. 2. On an upper surface of the side ring 100, exhaust ports 61 and 62 are formed at, for example, two locations so as to be spaced apart from each other in the circumferential direction. In other words, two exhaust ports are formed on the floor surface of the vacuum container 1. Exhaust ports 61 and 62 are formed in the side ring 100 at the positions corresponding to these exhaust ports.

In the present embodiment, the exhaust ports 61 and 62 are referred to as a first exhaust port 61 and a second exhaust port 62, respectively. In this regard, the first exhaust port 61 is formed at a position close to the second separation region D2 between the first process gas nozzle 31 and the second separation region D2 located at the downstream side in the rotational direction of the susceptor 2 with respect to the first process gas nozzle 31. The second exhaust port 62 is formed at a position close to the first separation region D1 between the plasma generating device 80 and the first separation region D1 at the downstream side in the rotational direction of the susceptor 2 with respect to the plasma generating device 80.

The first exhaust port 61 is used for exhausting the first process gas and the separation gas. The second exhaust port 62 is used for exhausting the plasma-processing gas and the separation gas. The first exhaust port 61 and the second exhaust port 62 are respectively connected to, for example, a vacuum pump 64 which is a vacuum disposal mechanism, via an exhaust pipe 63 in which a pressure regulation part 65 such as a butterfly valve or the like is installed.

As described above, the casing 90 is arranged from the side of the central region C to the outer edge side. Thus, when the gas flows from the upstream side in the rotational direction of the susceptor 2 with respect to the process region P2, the flow of the gas moving toward the second exhaust port 62 may be restricted by the casing 90 in some cases. Therefore, a groove-shaped gas flow path 101 for allowing the gas to flow is formed in the upper surface of the side ring 100 at the outer peripheral side of the casing 90.

As shown in FIG. 1, in the central portion of the lower surface of the top plate 11, there is installed a protrusion portion 5 which is formed in a substantially ring shape in the circumferential direction continuously with the portion of the convex portion 4 at the side of the central region C. The lower surface of the protrusion portion 5 is formed at the same height as the lower surface (the ceiling surface 44) of the convex portion 4. A labyrinth structure portion 110 for preventing various gases form being mixed with each other in the central region C is disposed above the core portion 21 at the rotational central side of the susceptor 2 with respect to the protrusion portion 5.

As described above, the casing 90 is formed up to the position close to the central region C. Thus, the core portion 21 supporting the central portion of the susceptor 2 is arranged at the rotational central side such that the region of the core portion 21 above the susceptor 2 avoids the casing 90. Therefore, various gases are more likely to be mixed with each other at the side of the central region C than at the side of the outer edge portion. Therefore, by forming the labyrinth structure above the core portion 21, it is possible to obtain a gas flow path and to prevent gases from being mixed with each other.

As shown in FIG. 1, a heater unit 7 as a heating mechanism is installed in a space between the susceptor 2 and the bottom surface portion 14 of the vacuum container 1. The heater unit 7 is configured to heat the wafers W mounted on the susceptor 2 to, for example, room temperature to about 300 degrees C. via the susceptor 2. In FIG. 1, a cover member 71a is installed at the lateral side of the heater unit 7, and a covering member 7a for covering the upper side of the heater unit 7 is installed. Purge gas supply pipes 73 for purging the arrangement space of the heater unit 7 are installed at a plurality of positions in the circumferential direction in the bottom surface portion 14 of the vacuum container 1 under the heater unit 7.

As shown in FIG. 2, a transfer port 15 for transferring the wafer W between the transfer arm 10 and the susceptor 2 in the side wall of the vacuum container 1 is illustrated. The transfer port 15 is configured to be air-tightly opened and closed by the gate valve G.

The wafer W is delivered between the recess 24 of the susceptor 2 and the transfer arm 10 at a position opposite to the transfer port 15. Therefore, at the location corresponding to the delivery position under the susceptor 2, there are installed lift pins (not shown) for penetrating the recess 24 to lift the wafer W from the back surface, and a lift mechanism (not shown) therefor.

In addition, the plasma processing apparatus according to the present embodiment is installed with the control part 140 including a computer for controlling the operation of the entire apparatus. A program for performing a substrate processing process to be described later is stored in a memory of the control part 120. The program includes a group of steps combined so as to execute various operations of the apparatus. The program is installed into the control part 140 from a memory part 141 as a storage medium such as a hard disk, a compact disk, a magneto-optical disk, a memory card, a flexible disk or the like.

In the present embodiment, there has been described an example in which the plasma processing apparatus is applied to a film forming apparatus. However, the plasma processing apparatus according to the embodiment of the present disclosure may be applied to a substrate processing apparatus that performs a substrate process other than film formation, such as an etching apparatus or the like. Although there has been described an example in which the susceptor 2 is formed of a rotatable rotary table, the rotation of the susceptor 2 is not necessarily essential, because the antenna device and the plasma generating device according to the present embodiment can be applied to various substrate processing apparatuses in which the adjustment of plasma intensity is required.

### [Plasma Processing Method]

Hereinafter, a plasma processing method using the plasma processing apparatus according to the embodiment of the present disclosure will be described.

First, the antenna 83 is deformed into a predetermined shape depending on the process. For example, when deforming the antenna 83, the shape of the antenna 83 may be specified by a recipe. Alternatively, the control part 140 may make a determination from the contents of the recipe so as to change the shape of the antenna 83 to a predetermined shape. The deformation of the antenna 83 is automatically performed by the vertical movement mechanisms 87 individually installed for at least two of the antenna members 830a to 830d. Therefore, the operator does not need to interrupt the process and to adjust the antenna 83.

First, the wafer W is loaded into the vacuum container 1. When loading the substrate such as the wafer W or the like, the gate valve G is first opened. Then, while intermittently rotating the susceptor 2, the wafer W is mounted on the susceptor 2 via the transfer port 15 by the transfer arm 10.

Subsequently, the gate valve G is closed and the interior of the vacuum container 1 is kept at a predetermined pressure by the vacuum pump 64 and the pressure regulation part 65. In this state, the wafer W is heated to a predetermined temperature by the heater unit 7 while rotating the susceptor 2. At this time, a separation gas, for example, an Ar gas is supplied from the separation gas nozzles 41 and 42.

Subsequently, the first process gas is supplied from the first process gas nozzle 31 and the second process gas is supplied from the second process gas nozzle 32. Further, the plasma-processing gas is supplied from the plasma-processing gas nozzles 33 to 35 at a predetermined flow rate.

Various gases may be used for the first process gas, the second process gas and the plasma-processing gas depending on the application. A source gas may be supplied from the first process gas nozzle 31. An oxidizing gas or a nitriding gas may be supplied from the second process gas nozzle 32. The plasma-processing gas composed of an oxidizing gas or a nitriding gas similar to the oxidizing gas or the nitriding gas supplied from the second process gas nozzle 32 and a mixed gas containing a noble gas is supplied from the plasma-processing gas nozzles 33 to 35. As the noble gas, plural kinds of noble gases differing in ionization energy or radical energy may be used. Noble gases differing in kind or mixed at different mixing ratios may be used according to the supply regions of the plasma-processing gas nozzles 33 to 35.

Description will now be made by way of example on a case where the film to be formed is a silicon oxide film, the first process gas is an organic aminosilane gas, the second process gas is an oxygen gas, and the plasma-processing gas is a mixed gas of He, Ar and O₂.

As the susceptor 2 rotates, a Si-containing gas or a metal-containing gas is adsorbed onto the surface of the wafer W in the first process region P1. Then, the Si-containing gas adsorbed onto the wafer W is oxidized by an oxygen gas in the second process region P2. As a result, one or more molecular layers of a silicon oxide film, which is a thin film component, are formed and a reaction product is formed.

When the susceptor 2 further rotates, the wafer W reaches the plasma process region P3 where the silicon oxide film is modified by the plasma process. Regarding the plasma-processing gas supplied to the plasma process region P3, for example, a mixed gas of Ar, He and O₂ containing Ar and He at a ratio of 1:1 is supplied from the base gas nozzle 33, a mixed gas containing He and O₂ and not containing Ar is supplied from the outer gas nozzle 34, and a mixed gas containing Ar and O₂ and not containing He is supplied from the axis-side gas nozzle 35. On the basis of the gas supply from the base gas nozzle 33 for supplying a mixed gas containing Ar and He at a ratio of 1:1, a mixed gas having weaker modifying power than the mixed gas supplied from the base gas nozzle 33 is supplied to the central axis side region where the angular velocity is low and the plasma process amount tends to become large. In addition, a mixed gas having stronger modifying power than the mixed gas supplied from the base gas nozzle 33 is supplied to the outer peripheral side region where the angular velocity is high and the plasma process amount tends to become insufficient. As a result, the influence of the angular velocity of the susceptor 2 can be reduced, and the uniform plasma process can be performed in the radial direction of the susceptor 2.

In addition, as described above, the antenna 83 of the antenna device 81 and the plasma generating device 80 are deformed so as to perform the plasma process with high in-plane uniformity. Thus, it is possible to perform the plasma process with high in-plane uniformity. In cooperation with the above-described nozzles 33 to 35, it is possible to perform film formation with very high in-plane uniformity. That is to say, it is possible to combine the improvement in in-plane uniformity due to deformation of the antenna 83 and the improvement in in-plane uniformity due to the setting of the supply amount of the plasma-processing gas for each region. Thus, more appropriate adjustment can be performed.

In addition, even when a single nozzle is used, it is also possible to perform the plasma process with high in-plane uniformity, because the deformation of the antenna 83 is performed so as to enhance in-plane uniformity.

When the plasma process is performed in the plasma process region P3, the plasma generating device 80 supplies the high-frequency power of a predetermined output to the antenna 83.

In the casing 90, the electric field of the electric field and the magnetic field generated by the antenna 83 is reflected, absorbed or attenuated by the Faraday shield 95. Thus, the arrival of the electric field into the vacuum container 1 is hindered.

Furthermore, in the plasma processing apparatus according to the present embodiment, the conductive path 97a is installed at one end side and the other end side in the length direction of the slits 97 and the vertical surface 95b is formed at the lateral side of the antenna 83. Therefore, it is possible to block the electric field which is going around from the one end side and the other end side in the longitudinal direction of the slits 97 and is going toward the wafer W.

On the other hand, since the slits 97 are formed in the Faraday shield 95, the magnetic field passes through the slits 97 and reaches the inside of the vacuum container 1 via the bottom surface of the casing 90. In this way, at the lower side of the casing 90, the plasma-processing gas is turned into plasma by the magnetic field. As a result, it is possible to form plasma containing a large number of active species which are less likely to cause electrical damage to the wafer W.

In the present embodiment, as the rotation of the susceptor 2 continues, the adsorption of the source gas onto the surface of the wafer W, the oxidation of the source gas component adsorbed onto the surface of the wafer W, and plasma modification of the reaction product are performed many times in the named order. That is to say, the film forming process by an ALD method and the modification process of the formed film are performed many times by the rotation of the susceptor 2.

In the plasma processing apparatus according to the present embodiment, the second and first separation regions D2 and D1 are disposed along the circumferential direction of the susceptor 2 between the first and second process regions P1 and P2 and between the third and first process regions P3 and P1. Therefore, while the mixing of the process gas and the plasma-processing gas is inhibited by these separation regions D2 and D1, the respective gases are exhausted toward the exhaust ports 61 and 62.

Examples of the first process gas in the present embodiment may include silicon-containing gases such as a DIPAS [diisopropylaminosilane] gas, a 3DMAS [trisdimethylaminosilane] gas, a BTBAS [bis-tertiary-butylaminosilane] gas, a DCS [dichlorosilane] gas, an HCD [hexachlorodisilane] gas and the like.

In the case where the plasma processing method according to the embodiment of the present disclosure is applied to the formation of a TiN film, the first process gas may be a metal-containing gas such as a TiCl₄ [titanium tetrachloride] gas, a Ti (MPD)(THD) [titanium methyl pentane dionate bis tetramethyl heptane dionate] gas, a TMA [trimethylaluminum] gas, a TEMAZ [tetrakis ethylmethylamino zirconium] gas, a TEMHF [tetrakis ethylmethylamino hafnium] gas, a Sr (THD)₂ [strontium bis tetramethyl heptane dionate] gas or the like.

In the present embodiment, there has been described an example in which as the plasma-processing gas, an Ar gas and a He gas are used as the noble gas, and the noble gas is combined with a modifying oxygen gas. However, it is also possible to use other noble gases. Instead of the oxygen gas, an ozone gas or water may be used.

In the process of forming a nitride film, an NH₃ gas or an N₂ gas may be used for a modification purpose. Furthermore, if necessary, a mixed gas with a hydrogen-containing gas (a H₂ gas or an NH₃ gas) may be used.

As the separation gas, in addition to the Ar gas, it may be possible to use an N₂ gas or the like.

Although the flow rate of the first process gas in the film forming process is not limited, it may be set to, for example, 50 to 1,000 sccm.

The flow rate of the oxygen-containing gas included in the plasma-processing gas is not limited and may be, for example, about 500 to 5,000 sccm (as an example, 500 sccm).

The internal pressure of the vacuum container 1 is not limited and may be set to, for example, about 0.5 to 4 Torr (as an example, 1.8 Torr).

The temperature of the wafer W is not limited and may be, for example, about 40 to 650 degrees C.

Although the rotation speed of the susceptor 2 is not limited, it may be set to, for example, about 60 to 300 rpm.

As described above, according to the plasma processing method of the present embodiment, the antenna 83 is deformed so as to enhance the in-plane uniformity of the plasma process. It is therefore possible to perform the plasma process with high in-plane uniformity.

Furthermore, even when the process changes, the antenna 83 is automatically deformed into a shape corresponding to a subsequent process. Thus, the subsequent process can be started easily and quickly.

### EXAMPLES

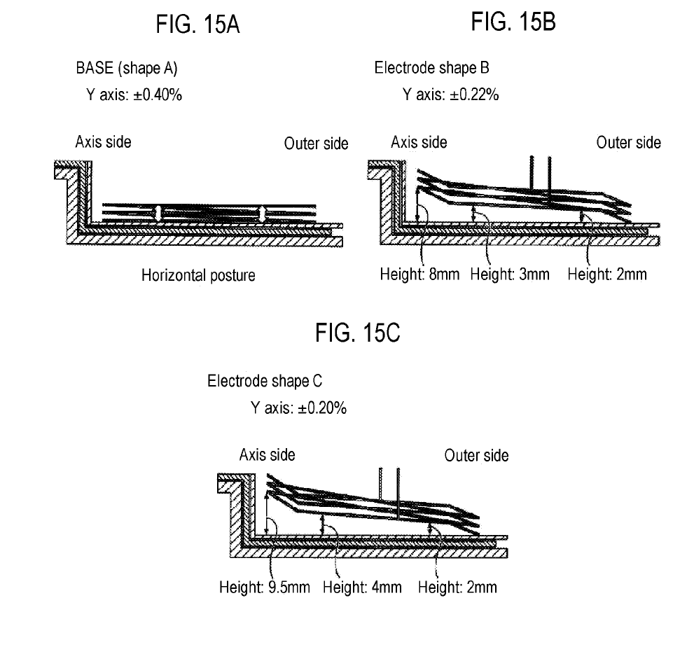

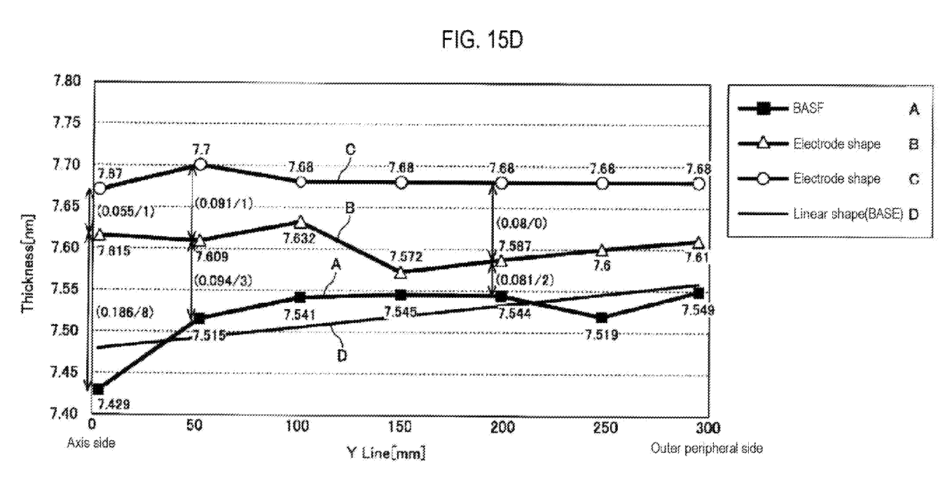

FIGS. 15A to 15D are views showing implementation results of the antenna device, the plasma generating device and the plasma processing apparatus according to the embodiment of the present disclosure. In the Example, film formation was performed by variously changing the shape of the antenna 83, and the in-plane uniformity on the Y axis of a film was evaluated. The Y axis is the same direction as the radial direction of the susceptor 2.

FIG. 15A is a view showing the shape of the antenna according to Comparative Example 1. As shown in FIG. 15A, in Comparative Example 1, the antenna 83 was not deformed and a SiO₂ film was formed using the antenna 83 horizontally mounted on the Faraday shield 95. In this case, the in-plane uniformity on the Y axis was ±0.40%.

FIG. 15B is a view showing the shape of the antenna according to Example 1. As shown in FIG. 15B, the antenna member 830a at the central axis side was bent upward and the antenna member 830b at the outer peripheral side was bent downward. The height of the antenna 83 at the central axis side was set to 8 mm. The height of the central antenna members 830c and 830d at a position closer to the center was set to 3 mm. The height of the central antenna members 830c and 830d at a position closer to the outer periphery was set to 2 mm. In this case, the in-plane uniformity on the Y axis was improved as compared with the case of Comparative Example 1 and was ±0.22%.

FIG. 15C is a view showing the shape of the antenna according to Example 2. As shown in FIG. 15C, the antenna member 830a at the central axis side was bent upward. The antenna member 830b at the outer peripheral side was bent downward. The height of the antenna 83 at the central axis side was set to 9.5 mm. The height of the central antenna members 830c and 830d at a position closer to the center was set to 4 mm. The height of the central antenna members 830c and 830d at a position closer to the outer periphery was set to 2 mm. In this case, the in-plane uniformity on the Y axis was ±0.20%. The in-plane uniformity on the Y axis was further improved as compared with the case of Example 1.

FIG. 15D is a view showing the results of a plasma process according to Comparative Example 1, Example 1, Example 2 and Comparative Example 2. In FIG. 15D, the horizontal axis represents the coordinate of the Y axis, and the vertical axis represents the thickness of the formed film. In Comparative Example 2, the shape of the antenna 83 is a straight shape obtained by merely inclining the antenna 83 of Comparative Example 1. The shape of the antenna 83 was not changed.

In FIG. 15D, the results of the plasma process according to Comparative Example 1, Example 1, Example 2 and Comparative Example 2 are indicated by characteristic curves A, B, C and D, respectively. As shown in FIG. 15D, it can be noted that the characteristic curve B according to Example 1 and the characteristic curve C according to Example 2 show more uniform film thickness and in-plane uniformity than the characteristic curve A according to Comparative Example 1 and the characteristic curve D according to Comparative Example 2. In particular, in the characteristic curve C according to Example 2, it can be understood that the film thickness remains the same, i.e., 7.68 nm, except the film thickness in the Y-axis coordinates 0 and 50, indicating substantially perfect in-plane uniformity.

As described above, the implementation results of the antenna device, the plasma generating device and the plasma processing apparatus according to the embodiment of the present disclosure reveal that, by changing the shape of the antenna 83, it is possible to perform the plasma process with very excellent in-plane uniformity. By automatically changing the shape of the antenna so as to achieve excellent in-plane uniformity, it is possible to perform the plasma process with high quality and high throughput.

According to the present disclosure in some embodiments, it is possible to automatically change the shape of an antenna and to easily change the shape of an antenna to an appropriate antenna shape for each process.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An antenna device, comprising:
a plurality of antenna members installed to extend along a predetermined circling shape having a longitudinal direction and a lateral direction, the antenna members including end portions connected to each other so as to form a pair in which connection portions in the longitudinal direction face each other in the lateral direction;
deformable conductive connection members configured to connect the end portions of the plurality of antenna members adjacent to each other; and
at least two vertical movement mechanisms individually installed in at least two of the plurality of antenna members and configured to change a bending angle of the antenna members using the connection members as fulcrums by vertically moving the at least two of the plurality of antenna members.

2. The device of claim 1, wherein the plurality of antenna members includes first and second antenna members configured to form opposite end portions in the longitudinal direction of the predetermined circling shape, and third and fourth antenna members configured to form central portions sandwiched between the opposite end portions and to face each other in the lateral direction.

3. The device of claim 2, wherein the at least two vertical movement mechanisms include a first vertical movement mechanism connected to the first antenna member, and second and third vertical movement mechanisms connected to the third and fourth antenna members, respectively.

4. The device of claim 3, wherein the first vertical movement mechanism and the second and third vertical movement mechanisms are configured such that when one performs a pull-up operation, the other remains fixed or performs a pull-down operation, and the first vertical movement mechanism and the second and third vertical movement mechanisms are configured to cooperate with each other to perform a bending of the first antenna member and the third and fourth antenna members.

5. The device of claim 2, further comprising:
a fulcrum jig configured to rotatably fix the second antenna member.

6. The device of claim 3, wherein the at least two vertical movement mechanisms include a fourth vertical movement mechanism connected to the second antenna member.

7. The device of claim 2, wherein the circling shape is a multi-stage circling shape formed at multiple stages by circling the antenna members multiple times, and positions of the connection members at the respective stages are aligned with each other in a plan view.

8. The device of claim 7, wherein spacers for maintaining a gap between the respective stages are installed at predetermined positions of the multi-stage circling shape.

9. The device of claim 2, further comprising:
a height measuring means configured to measure a height of the first antenna member.

10. The device of claim 9, wherein the height measuring means is a linear encoder.

11. The device of claim 1, wherein the connection members are made of copper.

12. The device of claim 1, wherein the at least two vertical movement mechanisms include air cylinders.

13. The device of claim 1, further comprising:
a wiring member connected to the plurality of antenna members and configured to supply an electric power to the plurality of antenna members,
wherein the wiring member has an elastic structure for absorbing the vertical movement of the plurality of antenna members.

14. A plasma generating device, comprising:
the antenna device of claim 1; and
a high-frequency power source configured to supply a high-frequency power to the antenna device.

15. A plasma processing apparatus, comprising:
a process chamber;
a susceptor installed inside the process chamber and configured to mount a substrate on a surface thereof; and
the plasma generating device of claim 14 installed on an upper surface of the process chamber.

16. The apparatus of claim 15, wherein the susceptor is configured to be rotatable, the surface of the susceptor is circular, a substrate mounting region on which the substrate is mounted along a radial direction is installed on the surface of the susceptor,
the plurality of antenna members of the plasma generating device are installed so that the longitudinal direction coincide with the radial direction of the susceptor, and one of the at least two vertical movement mechanisms is installed at the rotational central side of the susceptor.

17. The apparatus of claim 16, further comprising: a source gas supply region in which a source gas is supplied to the susceptor and a reaction gas supply region in which a reaction gas reacts with the source gas to produce a reaction product, which are installed in a mutually spaced-apart relationship in a circumferential direction of the susceptor,
wherein the plasma processing apparatus is installed above the reaction gas supply region.
